(19) United States
(12) Patent Application Publication
(10) Pub. No.: US 2020/0173882 A1
(43) Pub. Date: Jun. 4, 2020

(54) METHOD FOR DETERMINING STRESS LEVELS IN A MATERIAL OF A PROCESS ENGINEERING APPARATUS

(71) Applicant: Linde Aktiengesellschaft, München (DE)

(72) Inventors: Andreas KROENER, Wolfratshausen (DE); Martin POTTMANN, Wolfratshausen (DE); Oliver SLABY, München (DE)

(21) Appl. No.: 16/628,290

(22) PCT Filed: Jul. 6, 2018
(86) PCT No.: PCT/EP2018/025184

§ 371 Date: Jan. 3, 2020

(30) Foreign Application Priority Data
Jul. 19, 2017 (EP) 17020311.1

(51) Int. Cl. G01M 5/00; G01M 99/00; F28D 9/00

(52) U.S. Cl. CPC G01M 5/0041; G06F 30/23; F28D 9/0068; G01M 99/002

(57) ABSTRACT

The present invention relates to a method for determining a number of mechanical stresses (304) prevailing at different first locations in a material of a process engineering apparatus (1), wherein the number of mechanical stresses (304) prevailing at the different first locations in the material of the process engineering apparatus (1) is determined from a number of temperatures (301) prevailing at different second locations in the material of the process engineering apparatus using an empirical model (M3), the empirical model (M3) being trained by means of training data (207′), which are derived using a thermos-hydraulic process Simulation model (M1) and a structural-mechanical model (M2) of the process engineering apparatus (1).

The present invention relates to a method for determining a number of mechanical stresses prevailing at different first locations in a material of a process engineering apparatus, and to a computing unit and a computer program for performing this method.

### BACKGROUND OF THE INVENTION

Process engineering (also called chemical engineering) apparatuses are usually understood to be apparatuses for carrying out substance modifications and substance conversions with the aid of purposeful physical and/or chemical and/or biological and/or nuclear effects. Such modifications and conversions typically comprise crushing, sieving, mixing, heat transferring, cohobating, crystallizing, drying, cooling, filling, and superimposed substance transformations, such as chemical, biological or nuclear reactions.

Attempts are often made to monitor systems or components thereof by detecting and evaluating suitable variables such as vibrations, in order to be able to recognize faults and failures as early as possible (so-called condition monitoring). For this purpose, the system components to be monitored are equipped with suitable sensors in order to measure relevant variables and to feed them to the evaluation. Vibrations can often be related to the system state to determine a failure probability or remaining lifetime of components, in particular for a variety of rotating equipment such as pumps, compressors, turbines, etc.

However, such sound or vibration measurements are not suitable for most static process engineering equipment which is flowed through by fluids such as, for example, heat exchangers or distillation or adsorption or wash columns. Their material (metal) is also subject to material fatigue, but not due to vibrations, but due to stress fluctuations caused by pressure changes and—more importantly—temperature changes.

E.g. lifetime is reduced every time the equipment or apparatus experiences a stress cycle of a certain magnitude. This typically occurs during plant start-up, transitions between operating scenarios, or following process upsets, caused for instance by machine trips. In general, the amount of lifetime consumed strongly depends on the way the process is operated—however, the operating personnel currently does not have any clear indication of the impact of the operation on the stress levels of the apparatus (and, consequently, lifetime expectance). The only information available is inlet and outlet stream temperatures and (possibly) a few surface metal temperatures. Some basic guidelines are often provided which mostly aim at avoiding large temperature gradients at the few locations where temperature measurements are available.

It is known to determine stress levels for Plate-Fin Heat Exchangers (PFHE) via Finite-Element-Methods (cf. P. Freko “Optimization of Lifetime Expectance for Heat Exchangers with Special Requirements”, Proc. IHTC15-9791, 2014). However, this approach is limited to off-line analysis due to the complex and time-consuming nature of the calculations.

The application of surrogate modelling/machine learning has been reported previously for the approximation of finite element method (FEM) models in other application areas, such as mechanical design of machine components (cf. Wang, C. G. and S. Shan, Review of Metamodeling Techniques in Support of Engineering Design Optimization, J. Mechanical Design (2006)).

It is thus desirable to have the possibility to estimate stress at different locations of the engineering equipment, preferably on-line, from available measurements of inlet and outlet stream condition and equipment surface temperatures.

### DISCLOSURE OF THE INVENTION

According to the invention, a method for determining a number of mechanical stresses prevailing at different first locations in a material of a process engineering apparatus, i.e. an apparatus for carrying out substance modifications and/or substance conversions, and a computing unit for performing this method with the features of the independent claims are proposed. Advantageous further developments form the subject matter of the dependent claims and of the subsequent description.

The invention is based on the measures that the number of mechanical stresses prevailing at the different first locations in the material of the process engineering apparatus can be determined from a number of temperatures prevailing at different second locations in the material of the process engineering apparatus using an empirical model. The empirical model is trained by means of training data, which is derived using a thermo-hydraulic process simulation model and a structural-mechanical model of the process engineering apparatus. It has to be stressed that the first locations can be chosen arbitrarily, especially arbitrarily narrow or wide spaced, and independently from the second locations. Temperatures can be measured at the second locations using sensors, which can be located inside or outside of the process engineering apparatus.

Thermo-hydraulic model preferably uses first-principles (i.e. mass and energy balances and optionally momentum balances) to predict the behaviour of the engineering apparatus in the context of the overall engineering process it is a component of. For the example of a plate-fin heat exchanger, the thermo-hydraulic model predicts from given stream inlet conditions (composition, flowrate, temperature, pressure) outlet conditions (composition, flowrate, temperature, pressure, phase state) for all streams, as well as the local stream conditions, and heat transfer coefficients associated with the streams while they are passing through the engineering apparatus, and an approximate one dimensional (1-D) or two dimensional (2-D) metal temperature distribution of the equipment metal. Such a thermo-hydraulic simulation can be performed for any scenario the apparatus can be expected to experience. However, a detailed three dimensional (3-D) temperature distribution of the metal within the engineering apparatus is typically not considered by this type of process simulation.

Therefore, a separate structural-mechanical model is utilized to focus on this aspect but also to predict 3-D thermal stress levels within the equipment. This is usually done using Finite-Element-Methods using previously calculated thermo-hydraulic simulation results, e.g. streams' temperature profiles, streams' temperature temporal and spatial gradients and heat transfer coefficient profiles, as boundary conditions.

For online prediction of mechanical stress, it is proposed to use a machine learning based combination of both modelling approaches, which correlates thermo-hydraulic results, e.g. metal temperature profiles, with structural mechanical results, e.g. mechanical stress level profiles.

Simulations of the thermo-hydraulic process model within the expected operating envelope of the process result advantageously in 1-D or 2-D stream temperature and heat transfer coefficient profiles. For a suitably selected subset of these profiles the structural-mechanical model can be used to provide stress predictions at chosen locations. A machine learning algorithm can then be applied to train the empirical model to predict stress at chosen first locations from the metal surface temperature measurements at second locations.

The present invention allows for (particularly on-line) stress estimation for process engineering apparatuses flowed through by fluids, e.g. heat exchanger or distillation and absorption and wash columns, through a combination of modelling and machine learning. A machine-learning algorithm is used to determine the relationship (i.e. empirical model) between the system's inputs and outputs using a training data set that is representative of all the behaviour found in the system.

Because stress in the material of process engineering apparatuses cannot be measured directly during operation, it has to be estimated from other measurements. Generally, stress can be calculated using the Finite-Element-Method (FEM) but this can be computationally expensive and not suitable for online stress monitoring. The present invention thus provides an approach which combines two physical models and a data-driven model in order to allow the fast, yet reasonably accurate, estimation of thermal stresses.

In the course of the present method particularly first of all an operating range of the process engineering apparatus is specified by identifying scenarios representative of what the process engineering apparatus is exposed to during operation. Using the example of a heat exchanger the scenarios can e.g. be defined as time series of flows, inlet temperatures and inlet pressures of streams.

These dynamic scenarios are simulated using a (1-D or 2-D) heat transfer model of the process engineering apparatus. This model can particularly calculate a corresponding time series of wall temperature profiles, stream temperature profiles, and heat transfer coefficient profiles. Each set of profiles for a particular point in time can describe a (transient) state of the process engineering apparatus.

A limited number of these states is particularly selected, e.g. by maximizing a harmonic mean distance between the selected profiles.

For every selected state, a corresponding stress profile is particularly calculated using a (3-D) structural mechanical model implemented in the Finite-Element-Method. A machine learning algorithm is then particularly applied to train a data-driven meta model which estimates the stress at a particular position based on a number of metal temperature measurements.

In particular, the present method uses physical models to generate a limited amount of information about the stress in a process engineering apparatus. It then utilizes this information to build a data-driven model for stress estimation. This data-driven meta model is particularly specific for a particular process engineering apparatus because design data of the corresponding process engineering apparatus is particularly used in both physical models.

Once the number of mechanical stresses (i.e. stress levels) is determined, known techniques and procedures (e.g. ALPEMA Standards, Brazed Aluminum Plate-Fin Heat Exchangers Manufacturer's Association) are available to advantageously estimate lifetime consumption. The lifetime consumption is advantageously based on local changes of the mechanical stress, especially on the amplitude of local stress changes, over time.

Preferably, the empirical model is a data-driven model. As e.g. disclosed in chapter 2 “Data-Driven Modelling: Concepts, Approaches and Experiences”, Practical Hydroinformatics, Computational Intelligence and Technological Developments in Water Applications, Water Science and Technology Library, Volume 68, 2008, data-driven modelling (DDM) is based on analysing the data about a system, in particular finding connections between the system state variables (input, internal and output variables) without explicit knowledge of the physical behaviour of the system. These methods represent large advances on conventional empirical modelling and include contributions e.g. from the following overlapping fields: artificial intelligence (AI); computational intelligence (CI), which includes artificial neural networks, fuzzy systems and evolutionary computing as well as other areas within AI and machine learning; soft computing (SC), which is close to CI, but with special emphasis on fuzzy rule-based systems induced from data; machine learning (ML), which was once a sub-area of AI that concentrates on the theoretical foundations used by CI and SC; data mining (DM) and knowledge discovery in databases (KDD) are focused often at very large databases. DM is seen as a part of a wider KDD. Methods used are mainly from statistics and ML; intelligent data analysis (IDA), which tends to focus on data analysis in medicine and research and incorporates methods from statistics and ML.

A computing unit according to the invention is, in particular programmatically, configured to carry out an inventive method, i.e. comprises all means for carrying out the invention.

Further aspects of the invention are a computer program with program code means for causing a computing unit to perform a method according to the invention, and a computer readable data carrier having stored thereon such a computer program. This allows for particularly low costs, especially when a performing computing unit is still used for other tasks and therefore is present anyway. Suitable media for providing the computer program are particularly floppy disks, hard disks, flash memory, EEPROMs, CD-ROMs, DVDs etc. A download of a program on computer networks (Internet, Intranet, Cloud applications, etc.) is possible.

Further advantages and embodiments of the invention will become apparent from the description and the appended figures.

It should be noted that the previously mentioned features and the features to be further described in the following are usable not only in the respectively indicated combination, but also in further combinations or taken alone, without departing from the scope of the present invention.

In the drawings

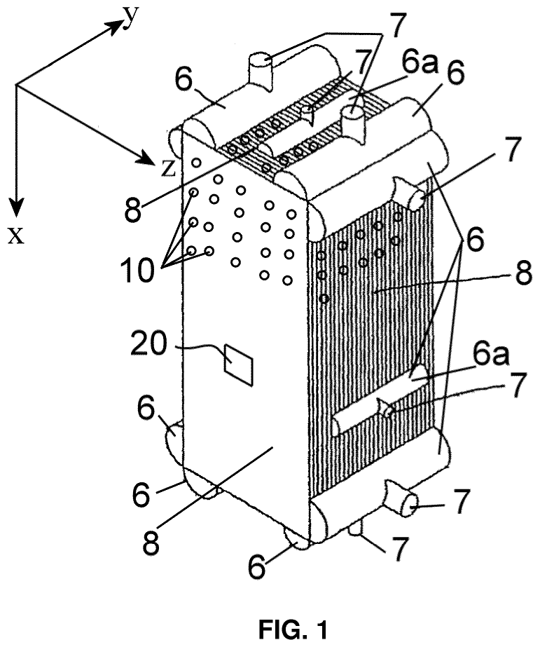

FIG. 1 shows schematically and perspectively a plate heat exchanger having a number of attachments,

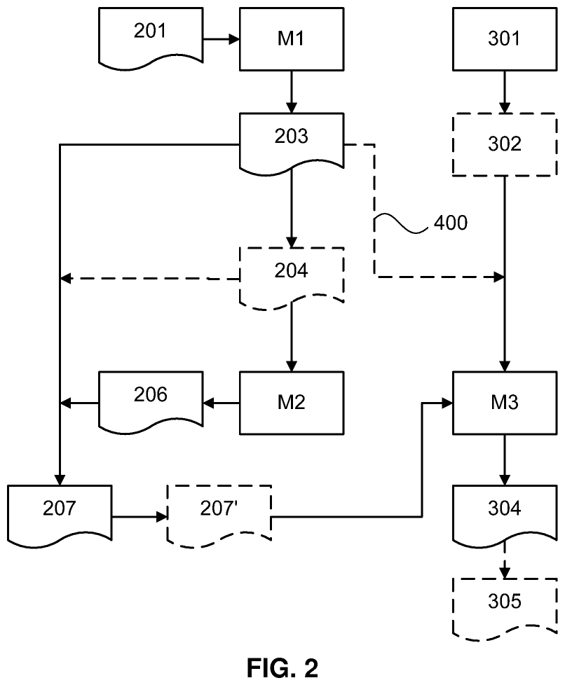

FIG. 2 shows schematically a method according to a preferred embodiment of the invention, and

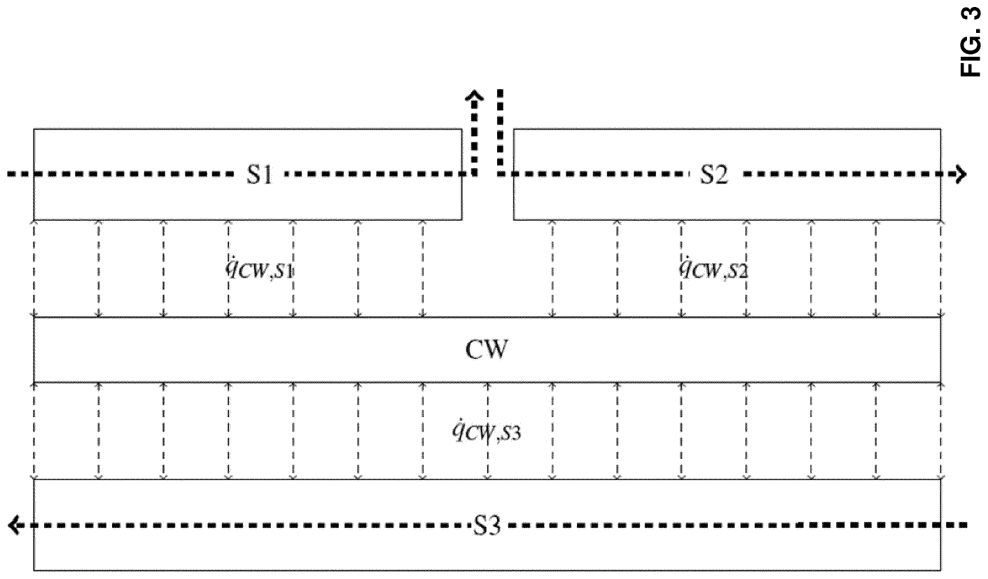

FIG. 3 shows schematically a model for a plate heat exchanger, which can be set up in the course of a preferred embodiment of the method according to the invention.

### DETAILED DESCRIPTION OF THE FIGURES

FIG. 1 schematically shows a process engineering apparatus implemented here as plate-type heat exchanger 1. The plate heat exchanger 1 comprises a substantially rectangular central body 8, e.g. having a length of some meters and a width or height about one or a few meters. The central body 8 has attachments 6, 6a on its sides.

Process streams which consist of one or more components and exhibit one or more fluid phases can be supplied to the plate-type heat exchanger or removed from it through nozzles 7. The attachments 6 and 6a are used to distribute the process fluids introduced through the nozzles 7 or to collect and remove them from the plate-type heat exchanger 1. Within the plate-type heat exchanger 1, the different process streams exchange heat energy.

The plate-type heat exchanger shown in FIG. 1 is designed to route process streams in separate passages past one another for heat exchange. Some of the streams can be routed past one another in opposite directions, some via crossing, and some in parallel directions.

Essentially the central body 8 is a cuboid of separating plates and heat exchange profiles, so-called fins, or distributor profiles. Layers which have separating plates and profiles alternate. A layer which has a heat exchange profile and distributor profiles is called a passage.

The central body therefore has passages and separating plates parallel to the flow directions in alternation. Both the separating plates and also the passages are usually made of aluminum. To their sides the passages are closed by aluminium beams so that a side wall is formed by the stacked construction with the separating plates. The outside passages of the central body 8 are hidden by an aluminum cover which is parallel to the passages and the separating plates.

The cuboid can be produced by applying a solder to the surfaces of the separating plates and subsequently stacking the separating plates and passages on top of one another in alternation. The covers cover the stack to the top or bottom. Then the stack can be soldered by heating in a furnace encompassing the stack.

On the sides of the plate-type heat exchanger 1 the distributor profiles have distributor profile accesses. Process Streams can be introduced into the pertinent passages via the attachments 6 and 6a and nozzles 7 or also removed again through these accesses. The distributor profile accesses are hidden by attachments 6 and 6a.

It is known from EP 1 798 508 A1 to determine temperature stresses of a plate-type heat exchanger during its operation by a 3-D numerical simulation. Based on the computed temperature stresses, the strength or remaining lifetime of the plate-type heat exchanger can be determined.

Within the invention, a different approach for determining stress levels is proposed, as described in reference to FIG. 2.

According to the preferred embodiment shown in FIG. 2, two physical models of different complexity are used—a (thermo-hydraulic) process simulation model M1 and a structural-mechanical model M2. The results obtained from these models are used to train a data-based (empirical) model for stress predictions M3.

For the example of the plate-fin heat exchanger 1, the thermo-hydraulic model M1 predicts from given stream inlet conditions, particularly composition, flowrate, temperature, and pressure, outlet conditions, particularly composition, flowrate, temperature, pressure, and phase state, for all streams, as well as the local stream conditions, and heat transfer coefficients associated with the streams while they are passing through the engineering apparatus. Further an approximate one dimensional (1-D) and/or an approximate two dimensional (2-D) metal temperature distribution of the equipment metal is especially predicted.

The data-based empirical model M3 is a data-driven model and is particularly based on analysing the data about a system, in particular finding connections between the system state variables (input, internal and output variables) without explicit knowledge of the physical behaviour of the system.

First, the likely operating ranges 201 of the heat exchanger are determined. These include values for e.g. stream flow rates, stream compositions, stream inlet and/or outlet temperatures and/or pressures, sequences of their occurrence, and the speed of transition between the values. It is assumed that the conditions under which the heat exchanger 1 will be operated during its lifetime are known (e.g. start-up and shutdown procedures, operating ranges of key process variables, possible process up-sets).

The operating ranges 201 are specified by identifying scenarios representative of what the heat exchanger 1 is exposed to during operation. The scenarios are defined as time series of flows \dot{n}ᵢ(t), inlet temperatures T_{in,i}(t) and inlet pressures p_{in,i}(t) of all streams i in the heat exchanger.

In particular, actual operating ranges 201 are defined, not design operating ranges. The scenarios identified in these operating ranges 201 are used as input to the structural-mechanical model M2 which generate data for the data-based empirical meta model M3.

For example several critical scenarios can be identified, which occur frequently and can produce high stress, namely warm start-up, cold start-up, change of operating case and deriming. These three scenarios are described by a sequence of flows \dot{n}ᵢ(t), inlet temperatures T_{in,i}(t) and inlet pressures p_{in,i}(t) of all streams i.

(Dynamic) process simulations of the exchanger (model M1) are performed within the envelope of the expected operating range 201. Preferably, the heat exchanger modelling approach used for this purpose results in one-dimensional (1-D) stream and/or material (wall) temperature profiles and/or heat transfer coefficient profiles 203 along the length of the exchanger. These profiles 203 are determined for every stream attached to the heat exchanger. In a second approach these profiles 203 are alternatively or additionally determined for each layer of the heat exchanger resulting in 2-D profiles of stream temperatures and/or material (wall) temperatures and/or heat transfer coefficients profiles 203. Naturally, via dynamic simulations such profiles are determined for every time step of the simulation.

For the heat exchanger modelling approach the process simulator “OPTISIM” can be used, which is an equation based simulator developed by the Applicant. In this simulator, a process is described by a set of equations which is solved simultaneously. A detailed description and validation of this process simulator is given by Woitalka et al., 2015 (Woitalka, Alexander, Thomas, Ingo, Freko, Pascal, & Lehmacher, Axel. 2015 (May). Dynamic Simulation of Heat Exchangers Using Linde's In-house Process Simulator OPTISIM®. In: Proceedings of CHT-15. ICHMT International Symposium on Advances in Computational Heat Transfer).

A schematic drawing of a first-principle model for a plate-fin heat exchanger is shown in FIG. 3. Particularly, an example for a heat exchanger with three streams S1, S2 and S3 is shown in FIG. 3, where the stream S3 flows counter-current to the streams S1 and S2 is. In this case, the entire metal of the heat exchanger is described by one heat capacity model CW. This is called a “common-wall” approach. By contrast, a PFHE can also be described by a “layer-by-layer” approach using one heat capacity model for every layer of the PFHE.

As is described in U.S. Pat. No. 7,788,073 B2 these temperature and heat transfer coefficient profiles 203 can be used as input for a separate 3-D structural-mechanical model (preferably a FEM model) M2. This model then predicts the 3-D temperature distribution and a corresponding 3-D stress distribution 206. It is assumed that detailed geometry and other design data of the heat exchanger in question are available.

Preferably in a selection step, only a small fraction 204 of the profiles 203 generated via model M1 are selected to be processed by model M2. This selection shall be done optimally in a fashion that the overall temperature envelope (envelope of all temperature profiles exhibited within the overall operating range) of the heat exchanger is covered as uniformly as possible.

A 1-D heat transfer model is computationally relatively cheap. This allows the quick simulation of many scenarios and the generation of a large number of temperature profiles S. Calculating the corresponding stresses using FEM, on the other hand, is computationally much more expensive and not feasible for such a large number of profiles. Instead, stress is calculated particularly for a small subset of profiles S*, yet still capturing as much variation as possible. To achieve this, a subset which is representative of the whole set is identified.

Assuming that the variation in stress mainly depends on the variation in the temperature profile, an optimal subset particularly consists of temperature profiles which are as “different from each other” as possible, i.e. such that the selected profiles spread evenly.

A way of measuring “even spread” in experimental design is the so called harmonic mean distance which is e.g. explained in Läuter, 1974 (Läuter, E. 1974. Experimental Design in a Class of Models. Mathematische Operationsforschung and Statistik, 5, 379-398), or in Carnell, 2016 (Carnell, Rob. 2016 (August). Latin Hypercube Samples.

https://CRAN.R-project.org/package=lhs).

In the course of this harmonic mean distance approach, firstly for a selection S* of N profiles, the pairwise Euclidian distance ΔT_{w,ij} between profiles is calculated:

$$Δ {T}_{w , ij} = \sqrt{{\sum }_{k = 1}^{n} {( {T}_{w , i} ( x = {x}_{k} ) - {T}_{w , j} ( x = {x}_{k} ) )}^{2}}$$

where n is the number of sampling points for which the heat transfer model calculates temperature. The Euclidian distance is proportional to the root mean square deviation and quantifies how different two profiles are.

Secondly, the harmonic mean ΔT̅_{w,harm} of the pairwise distances is calculated:

$$Δ {\overline{T}}_{w , harm} = \frac{N}{{\sum }_{( i , j )}^{N} ( \frac{1}{Δ {T}_{w , ij}} )}$$

If two of the selected profiles are very similar, their Euclidian distance is close to zero. This causes the harmonic mean distance ΔT̅_{w,harm} to be close to zero as well. This is true even if the selection includes pairs of profiles with a very large Euclidian distance. In contrast, if the harmonic mean distance is large for a set of selected profiles, the set does not contain similar profiles. Hence, the proposed way of selecting an optimal set of profiles is to maximize the harmonic mean distance between them.

Finding the subset of profiles S* with the largest harmonic mean distance is an optimization problem. Because profiles are selected from a set of existing profiles, the optimization problem is a combinatorial problem. One example to solve such problems are genetic algorithms, a class of stochastic search algorithms which are e.g. described by Scrucca, 2013 (Scrucca, Luca. 2013. GA: A Package for Genetic Algorithms in R. Journal of Statistical Software, 53(4), 1-37.).

The set of variables which are to be optimized are called an individual or a chromosome, while the variables themselves are called genes. For the problem of selecting suitable temperature profiles an individual corresponds to a set of selected profiles. The individual's genes are index numbers where each index number corresponds to one particular profile.

Summarising, in order to select an optimal set of profiles, the harmonic mean distance is maximised (Läuter, 1974) between a minimal fraction of profiles 204 with preferably a genetic algorithm (Scrucca, 2013).

For every selected profile FEM calculations are performed via model M2 to determine the corresponding 3-D stress distribution 206. Since stress levels at every location of the exchanger are not strictly required for equipment monitoring purposes, it is preferred that the 3-D stress distribution is reduced to a lower-dimensional representation, such as a 1-D profile obtained by selecting the maximum stress over the heat exchanger cross section (directions y, z) for every position (direction x) along the flow direction of the exchanger or such as a 2-D profile obtained by selecting the maximum stress over the heat exchanger width (direction z) for every position (direction x) along the flow direction and for each layer (direction y) of the exchanger.

Since the estimation of lifetime expectance from stress predictions shall be done independently for different locations of the heat exchanger block, a spatial resolution of sufficient detail needs to be preserved. Reducing the 3-D stress distribution to a 1-D or 2-D profile as described above is just one example of performing this reduction of dimensionality. In some cases—for instance, if headers are attached to the exchanger or punctual weld joints exist at about the same location x, but on different sides of the exchanger—it may be necessary to capture multiple (stress) points for every location x or x, y of the exchanger. In this manner, it is possible to distinguish between stress conditions associated with the different headers or weld joints, which are to be treated separately from the perspective of lifetime estimation.

In general, FEM is a numerical approximation method for partial differential equations (PDEs) which discretizes the complex geometry of the problem domain into small sub-domains called elements. In each element, the PDE is replaced by a local ordinary differential or algebraic equation. The resulting system of equations can be solved to give an approximate solution of the underlying PDE.

Calculating stress in PFHEs is in detail described by Hölzl, 2012 (Hölzl, Reinhold. 2012. Liftime Estimation of Aluminum Plate Fin Heat Exchangers. In: Proceedings of the ASME 2012 Pressure Vessels & Piping Division Conference), as well as in document U.S. Pat. No. 7,788,073 B2.

For example, a detailed, three dimensional model of the PFHE's geometry can be used, wherein the complete sequence of layers, partition plates, sidebars and headers can be considered. The corrugated sheets can be replaced by solid plates with modified mechanical and thermal constants. This way, it is not necessary to model the detailed geometry of the fins but the influence of different fin types is still considered in the analysis.

The governing PDEs for calculating stress in a PFHE are the energy and momentum balances of the metal. For example, a coupled thermal-mechanical analysis can be performed, in the course of which firstly the energy balance is solved, thereby calculating the metal temperature distribution. Subsequently, the momentum balances is solved calculating the stress distribution.

Once considered profiles 203 or 204 are processed by model M2, a data set 207 is available consisting of 1-D or 2-D metal temperature profiles 203 or 204 and the corresponding 3-D stress distribution resp. its lower-dimensional approximation 206. Machine learning (e.g. Similarity Based Modeling—cf. Wegerich, S, Similarity Based Modeling of Time synchronous Averaged Vibration Signals for Machinery Health Monitoring, Proceedings, 2014 IEEE Aerospace Conference, Vol. 6, Big Sky, MT, 6-13.05.2004; U.S. Pat. No. 7,308,385 B2) is now used to train the empirical model M3 to predict a 3-D stress distribution resp. its lower dimensional approximation from 1-D or 2-D metal temperature profiles.

Thus, machine learning is used to generate a data-driven model M3 which can quickly estimate stress. For this purpose, Gaussian Process Regression (GPR) can be used. GPR is method for meta-modeling of FEM results, which is e.g. described by Rasmussen & Williams, 2006 (Rasmussen, C. E., & Williams, C. K. I. 2006. Gaussian Processes for Machine Learning. Adaptive Computation and Machine Learning series. The MIT Press). A Gaussian process (GP) defines a probability distribution over functions and is a generalization of the simple Gaussian distribution.

In order to apply GPR to estimated stress, a dependent variable of the regression is stress or, more specifically, the maximum stress σₓ in the cross section of the PFHE at a particular position x along its length. Independent variables are the available wall temperature measurements \vec{T}ₘ=\vec{T}_{measured}.

The training set of the GPR is particularly made up of the stress σₓ(x) at location x calculated by the structural mechanical model M2 and the relevant metal temperatures \vec{T}ₘ calculated by the heat transfer model for each of the selected states S*. The metal temperatures could also be taken from the structural mechanical model M2. The GPR thus estimates the maximum stress for one particular location x.

Preferably, for the training of the data-driven model M3 only a subset 207′ of the available data is used, i.e. a training data set is first selected. The data not used for training are preferably used for model validation.

While different types of machine learning algorithms can be used for this purpose, the quality of the model predictions shall be a determining factor in choosing a suitable machine learning approach. The quality of the model prediction for every data point can be assessed via the error metric MAPE (mean absolute percentage error) over the entire 1-D or 2-D stress profile (or some other set of representative stress locations).

Training of the model implies that separate models be set up for every discrete location of the heat exchanger. In essence, if the approximation of the 3-D stress distribution consists of N locations (first locations according to claim 1) then N separate sub-models are trained to predict the stress at a particular location from the entire temperature profile (temperatures at second different locations according to claim 1).

The on-line prediction of thermal stress 304 is accomplished by providing temperature measurements 301 in lieu of the simulated temperature profiles from model M1 as inputs to model M3. This requires that sufficient temperature sensors are available.

According to a preferred embodiment of the invention, the plate-type heat exchanger 1 of FIG. 1 is thus equipped with a sufficient number of temperature sensors 10 and the stress levels are determined based on the sensor data. The temperature sensors 10 are connected with a computing unit 20 which is in turn especially configured for performing steps 301 and/or M1.

If sufficient temperature sensors are not available a model-based state estimation technique (e.g. Kalman Filter, Julier, Simon J., & Uhlmann, Jeffrey K. 2004. Unscented Filtering and Nonlinear Estimation. In: Proceedings of the IEEE, vol. 92. or Gelb, A. 1974. Applied Optimal Estimation, MIT Press.) can be used in step 302 to estimate a more detailed metal temperature profile from the available metal temperature and other measurements (e.g. flowrates and stream temperatures) of inlet and outlet streams or other process locations.

In order to set up this state estimation process 302, a process model should be available. This could be a process simulation model as described above in connection with M1. Alternatively, assuming that such a model is not available on-line, a separate empirical model needs to be set up instead. This model will predict the temperature profile at time k+1 from the temperature profile at time k and all other available measurements at time k (flows, stream temperatures, and a number of metal temperature measurements). The same methodology as used for training model M3 can be applied to train this model.

Particularly, a Kalman filter can be used as a state estimation method to estimate a more detailed temperature profile \vec{T}_{w}(t) based on a small number of available metal temperature measurements as well as other measured quantities. The Kalman filter is described in detail by Julier & Uhlmann (2004). First, the filter is particularly initialized with a known temperature profile \vec{T}_{w,0}. Based on \vec{T}_{w,0} and the measured flows \vec{\dot{V}}₀ at t₀, the temperature profile \vec{T}_{w,pred,1} at time t₁ is predicted in the prediction step. The independent variables of this model are \vec{T}_{w,k} and \vec{\dot{V}}ₖ while the predicted dependent variables are \vec{T}_{w,pred,k+1}.

In the update step, the deviation between the measured temperatures \vec{T}_{m,1} and the predicted values at the corresponding locations is calculated. The entire predicted temperature profile \vec{T}_{w,pred,1} is corrected based on this deviation. The updated temperature profile \vec{T}_{w,1} is used as an initial profile for the next time step and the procedure is repeated. A detailed discussion of the mathematical background can be found in Julier & Uhlmann (2004).

The trained machine learning algorithm M3 is computationally much more efficient and faster to execute than a recalculation of 3-D stress distribution with FEM model M2. Hence, it provides—for the first time—the options either to estimate stress levels on-line for a specific apparatus like a PFHE or to efficiently estimate stress levels of one or more apparatuses like PFHEs based on large data volumes taken from operation in an a-posteriori data analysis. In turn, on-line stress estimation provides the basis for tracking the lifetime expectancy of the apparatus.

In an optional step 305 the stress predictions are used to determine an estimated life time consumption of the apparatus. For this purpose the stress predictions over time are considered, independently for all first locations, and the number of cycles, mean values and amplitude of stress changes are counted (either on-line or in batch-mode for certain time periods) based on known principles such as “rainflow counting” (e.g. M. Mussalam, C. M. Johnson, An Efficient Implementation of the Rainflow Counting Algorithm for Life Consumption Estimation, IEEE Transactions Reliability, Vol 61, Issue 4, 2012). The stress cycle information for first locations is then transformed into an estimate of life time consumption according published standards such as AD 2000-Merkblatt S2 Analysis for cyclic loading (AD2000 Code, Beuth Verlag, Berlin, 2017).

The application described above is a “predictive” type of estimation—i.e. given certain process conditions as observed by plant measurements, it predicts the corresponding stress at different locations of the exchanger. However, the invention is not limited to this predictive aspect. It can also be applied in a simulation or “preventive” mode, where it is used to assess the impact of a certain operating strategy on the lifetime consumption of the apparatus. In this mode model M1 is simulating the operating scenario by choosing the selected behaviour of process boundary conditions—manipulations of all streams entering the exchanger in terms of temperature, pressure, flows, and compositions. The predictions of metal wall temperature (output of model M1) is directly fed into model M3, as shown by connection 400, and the impact of this operating scenario on the expected stress levels of the apparatus at different locations is immediately seen. If a planned operating change results in large stress levels the operators can vary the operating approach in a manner such that lower stress levels are seen.

Furthermore, the stress estimation via model M3 can be integrated into an optimal linear or non-linear model predictive control (LMPC, NLMPC, e.g. J. H. Lee, “Model Predictive Control: Review of the three decades of development”, Int. J. Control, Automation and Systems, 2011). In model predictive control (MPC) control of a multivariable system (i.e. multiple dependent variables are being controlled via multiple independent variables) is achieved by taking into account future process behaviour on the basis of a linear or nonlinear process model. The current (and future) control moves are determined via optimizing a suitable objective function that characterizes the desirable process behaviour over a certain prediction horizon. In this context the said stress estimation model M3, together with the process simulation model M1 can be used to obtain stress estimates over the controller's prediction horizon. The absolute stress levels or the changes over the prediction horizon for all or the selected critical loctions can now be included in the controller's objective function. With this approach it is possible to minimize the estimated impact of the process operation on the life time consumption of the apparatus being controlled.

A further embodiment of the invention relates to design optimization: The process of stress estimation can be used to determine a suitable number and suitable positions of temperature measurements with which thermal stress can be predicted at a desired level of accuracy. The temperature profiles from model M1 are provided at the resolution selected for simulation purposes. In general, the number of temperature measurements will be significantly smaller than the discretization of model M1. Hence, the process of training model M3 can be repeated multiple times using as model input different sets of temperature measurement locations. The model based on the smallest number of temperature measurements which still results in an acceptable accuracy of stress profile predictions then provides the recommendation as to where the temperature measurements should be located.

1. Method for determining a number of mechanical stresses (304) prevailing at different first locations in a material of a process engineering apparatus (1),
wherein the number of mechanical stresses (304) prevailing at the different first locations in the material of the process engineering apparatus (1) is determined from a number of temperatures (301) prevailing at different second locations in the material of the process engineering apparatus using an empirical model (M3),
the empirical model (M3) being trained by means of training data (207′), which are derived using a thermo-hydraulic process simulation model (M1) and a structural-mechanical model (M2) of the process engineering apparatus (1).

2. Method according to claim 1, wherein lifetime consumption is estimated based on the number of mechanical stresses.

3. Method according to claim 1, wherein the empirical model (M3) comprises a sub-model for every location of the different first locations.

4. Method according to claim 1, wherein the empirical model (M3) is a data-driven model.

5. Method according to claim 1, wherein the structural-mechanical model (M2) of the process engineering apparatus (1) is an, especially three-dimensional, FEM model.

6. Method according to claim 1, wherein output (203, 204) of the process simulation model (M1) comprises a three- or lower-dimensional temperature distribution and/or heat transfer coefficients.

7. Method according to claim 1, wherein output (203, 204) of the process simulation model (M1) is input to the structural-mechanical model (M2) of the process engineering apparatus (1) or to the empirical model (M3).

8. Method according to claims 6, wherein the output (204) of the process simulation model (M1) which is input to the structural-mechanical model (M2) comprises a subset of a three- or lower-dimensional temperature distributions, which preferably covers the overall operating range as uniformly as possible.

9. Method according to claim 1, wherein an operating range (201) of the process engineering apparatus is input to the process simulation model (M1).

10. Method according to claim 1, wherein output (206) of the structural-mechanical model (M2) is a three- or lower-dimensional stress distribution.

11. Method according to claim 1, wherein the number of temperatures prevailing at different second locations is measured by temperature sensors (10) and/or calculated using a model-based state estimation technique (302).

12. Method according to claim 1, wherein the number of mechanical stresses prevailing at the different first locations in the material of the process engineering apparatus (1) is additionally determined based on stream flow values and/or pressure values and/or stream temperature values.

13. Method according to claim 1, wherein the process engineering apparatus (1) is flowed through by fluids and/or is a heat exchanger or plate-fin-type heat exchanger or spiral-wound-type heat exchanger or a distillation column or a absorption column or a wash column.

14. Method according to claim 1, wherein determining the number of mechanical stresses (304) prevailing at the different first locations in the material of the process engineering apparatus (1) is integrated into a linear or non-linear model predictive control.

15. Computing unit (20) which is, in particular programmatically, configured to perform a method according to claim 1.
